(19) United States
(12) Patent Application Publication
(10) Pub. No.: US 2024/0379384 A1
(43) Pub. Date: Nov. 14, 2024

(54) WIRE GRIPPER, WIRE PROCESSING APPARATUS INCLUDING THE SAME, AND WIRE PROCESSING METHOD USING THE SAME

(71) Applicant: SAMSUNG ELECTRONICS CO., LTD., Suwon-si (KR)

(72) Inventors: Jongseong Ko, Suwon-si (KR); Daeyong Kim, Suwon-si (KR); Donghyun Kim, Suwon-si (KR); Pyungkang Kim, Suwon-si (KR); Kihong Park, Suwon-si (KR); Jungjoon Park, Suwon-si (KR); Jungjun Park, Suwon-si (KR); Jooyoung Park, Suwon-si (KR); Hoseok Song, Suwon-si (KR); Kongwoo Lee, Suwon-si (KR); Hyunyoung Lee, Suwon-si (KR); Chuyoung Choung, Suwon-si (KR); Jeongmin Hwang, Suwon-si (KR); Jisu Kim, Suwon-si (KR); Junhyeok Park, Suwon-si (KR); Chiho Ahn, Suwon-si (KR)

(21) Appl. No.: 18/608,633

(22) Filed: Mar. 18, 2024

(30) Foreign Application Priority Data
May 10, 2023 (KR) 10-2023-0060377
Sep. 5, 2023 (KR) 10-2023-0117988

(51) Int. Cl. H01L 21/67

(52) U.S. Cl. CPC H01L 21/67011

(57) ABSTRACT

The present disclosure relates to wire grippers, wire processing apparatuses, and wire processing methods. An example wire gripper comprises a gripper body, a wire supply in the gripper body and supplying a wire, a wire cutting section including a cutter that cuts the wire supplied from the wire supply, a pressure roller below the wire supply and providing a guide groove to guide the wire supplied from the wire supply, a twister on a side of the pressure roller, and a reloader that drives an end of the wire to move from the wire supply to the twister. The twister holds and twists the end of the wire guided by the pressure roller.

### CROSS-REFERENCE TO RELATED APPLICATIONS

This application claims priority under 35 U.S.C § 119 to Korean Patent Applications No. 10-2023-0060377 filed on May 10, 2023, and No. 10-2023-0117988 filed on Sep. 5, 2023, in the Korean Intellectual Property Office, the disclosures of which are hereby incorporated by reference in their entirety.

### BACKGROUND

Various processes may be performed to fabricate a semiconductor device. For example, a substrate may undergo a photolithography process, an etching process, and a deposition process in fabricating a semiconductor device. Many semiconductor fabrication apparatuses are needed for the semiconductor fabrication process. In addition, it may be required to automate the use, setup, and management of semiconductor fabrication apparatuses for efficiency of semiconductor fabrication process.

### SUMMARY

The present disclosure relates to wire grippers, including a wire gripper capable of automatically pressing a wire into a substrate processing apparatus, a wire gripper capable of automatically preparing a next wire press-in process after a previous wire press-in process, a wire gripper capable of fixedly twisting an end of a wire and pressing the wire with its reduced diameter, and a wire gripper capable of receiving a wire from a wire supply to hold an end of the wire to a twister, wire processing apparatuses including the same, and wire processing methods using the same.

The object of the present disclosure is not limited to the mentioned above, and other objects which have not been mentioned above will be clearly understood to those skilled in the art from the following description.

In some implementations, a wire gripper comprises: a gripper body; a wire supply in the gripper body and supplying a wire; a wire cutting section including a cutter that cuts the wire supplied from the wire supply; a pressure roller below the wire supply and providing a guide groove to guide the wire supplied from the wire supply, the pressure roller rotating about a first axis; a twister on a side of the pressure roller; and a reloader that drives an end of the wire to move from the wire supply to the twister. The twister may hold and twist the end of the wire guided by the pressure roller.

In some implementations, a wire processing apparatus comprises: a wire gripper; and a manipulator combined with the wire gripper and causing the wire gripper to move. The wire gripper may include: a gripper body; a rotatable cylindrical wire supply in the gripper body; a wire cutting section that cuts a wire supplied from the wire supply; a cylindrical pressure roller that guides a movement of the wire; and a twister that twists an end of the wire guided by the pressure roller.

In some implementations, a wire processing method comprises: placing a wire on a wire gripper; and placing the wire into a substrate processing apparatus. The wire gripper includes: a wire supply that supplies the wire; a wire cutting section including a cutter that cuts the wire supplied from the wire supply; and a pressure roller that pressurizes the wire toward the substrate processing apparatus, the wire being supplied from the wire supply. The step of placing the wire into the substrate processing apparatus includes: allowing the wire gripper to place an end of the wire into the substrate processing apparatus; and allowing the pressure roller to move while pressurizing the wire placed in the substrate processing apparatus.

Details of other example implementations are included in the description and drawings.

### BRIEF DESCRIPTION OF THE DRAWINGS

FIG. 1 illustrates a simplified diagram showing an example of a substrate processing apparatus.

FIG. 2 illustrates a perspective view showing an example of a wire processing apparatus and a portion of an example of a substrate processing apparatus.

FIG. 3 illustrates an exploded perspective view showing an example of a wire gripper.

FIG. 4 illustrates a perspective view showing an example of a wire gripper.

FIG. 5 illustrates a front view showing an example of a wire gripper.

FIG. 6 illustrates a side view showing an example of a wire gripper.

FIG. 7 illustrates an enlarged perspective view of an example of a wire cutting section.

FIG. 8 illustrates a front view showing an example of an aperture-shaped grip part.

FIG. 9 illustrates a front view showing an example of an aperture-shaped grip part.

FIG. 10 illustrates a perspective view showing an example of a wire processing apparatus.

FIG. 11 illustrates a flow chart showing an example of a wire processing method.

FIG. 12 illustrates a perspective view showing an example of a wire gripper according to the flow chart.

FIG. 13 illustrates a perspective view showing another example of a wire gripper according to the flow chart.

FIG. 14 illustrates a perspective view showing another example of a wire gripper according to the flow chart.

FIG. 15 illustrates a perspective view showing another example of a wire gripper according to the flow chart.

FIG. 16 illustrates a perspective view showing another example of a wire gripper according to the flow chart.

### DETAILED DESCRIPTION

The following will now describe some implementations of the present disclosure with reference to the accompanying drawings. Like reference numerals may indicate like components throughout the description.

In this description, symbol D1 may indicate a first direction, symbol D2 may indicate a second direction that intersects the first direction D1, and symbol D3 may indicate a third direction that intersects each of the first direction D1 and the second direction D2. The first direction D1 may be called an upward direction, and a direction opposite to the first direction D1 may be called a downward direction. In addition, each of the second and third directions D2 and D3 may be called a horizontal direction.

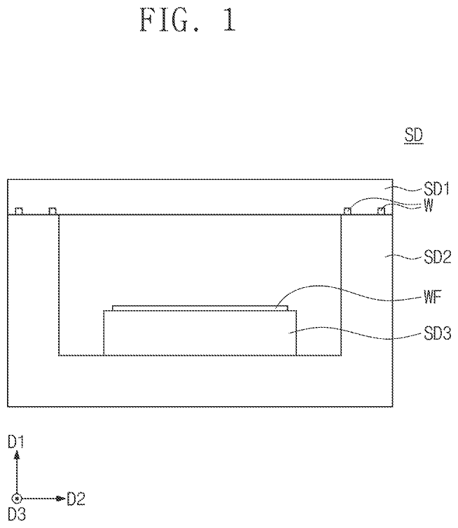

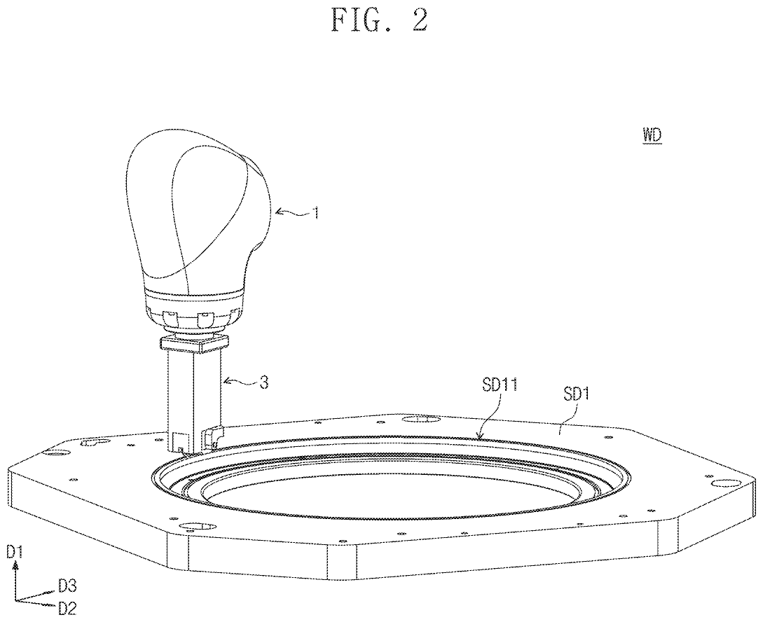

FIG. 1 illustrates a simplified schematic diagram showing an example of a substrate processing apparatus SD. FIG. 2 illustrates a perspective view showing an example of a wire processing apparatus WD and a portion of an example of a substrate processing apparatus SD.

Referring to FIG. 1, the substrate processing apparatus SD may be provided. The substrate processing apparatus SD may include an apparatus for performing a semiconductor fabrication process. For example, the substrate processing apparatus SD may be one of apparatuses for performing a chemical mechanical polishing (CMP) process, a deposition process, an etching process, an oxidation process, a photolithography process, and a packaging process on a substrate. However, the type of the substrate processing apparatus SD is not limited thereto, and the substrate processing apparatus SD may include any type of device capable of pressing a wire W into a narrow gap.

The substrate processing apparatus SD may include a lower process body SD2, a stage SD3, and an upper process body SD1. The lower process body SD2 may provide a process space (not designated by reference numeral). The stage SD3 may be positioned in the lower process body SD2. The stage SD3 may support a substrate WF. The upper process body SD1 may be coupled onto the lower process body SD2. The upper process body SD1 may hermetically seal the process space.

One or both of the lower and upper process bodies SD2 and SD1 may provide a groove (see SD11 of FIG. 2). The wire W may be inserted into the groove SD11. For example, the wire W may be pressed into the groove SD11. When the wire W is pressed into the groove SD11, a thermal conductivity and an electrical conductivity may increase. The wire W may include a metal wire. The wire W may include a spiral wire, but the present disclosure is not limited thereto.

Referring to FIG. 2, there may be provided a portion of the substrate processing apparatus SD and the wire processing apparatus WD. The wire processing apparatus WD may include a manipulator 1 and a wire gripper 3. The manipulator 1 may be combined with the wire gripper 3. The manipulator 1 may drive the wire gripper 3 to move. The manipulator 1 may provide the wire gripper 3 with power. However, the function of the manipulator 1 is not limited thereto. The manipulator 1 may apply a pneumatic pressure to the wire gripper 3. The manipulator 1 may have a function required for automation of press-in of the wire W. The manipulator 1 may drive the wire gripper 3 to move to insert the wire W into the groove SD11 of the substrate processing apparatus SD. The wire gripper 3 will be discussed in detail below.

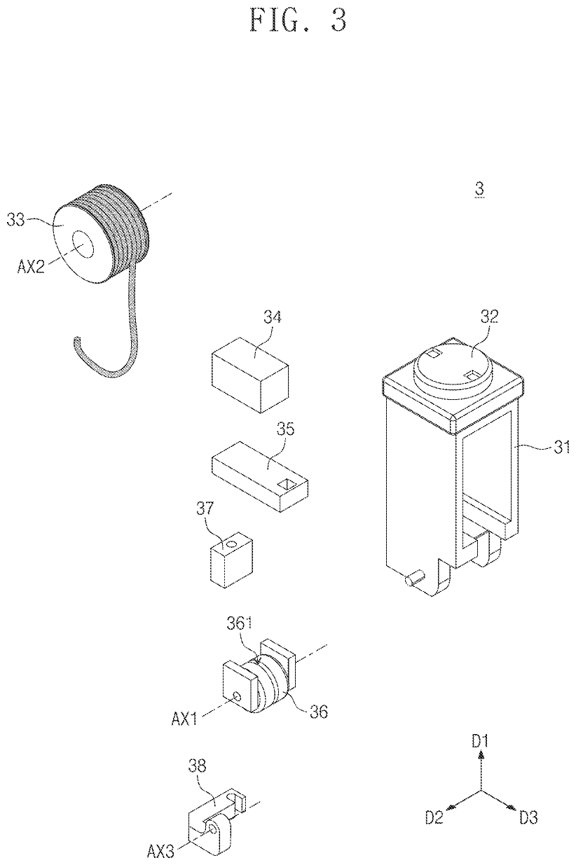

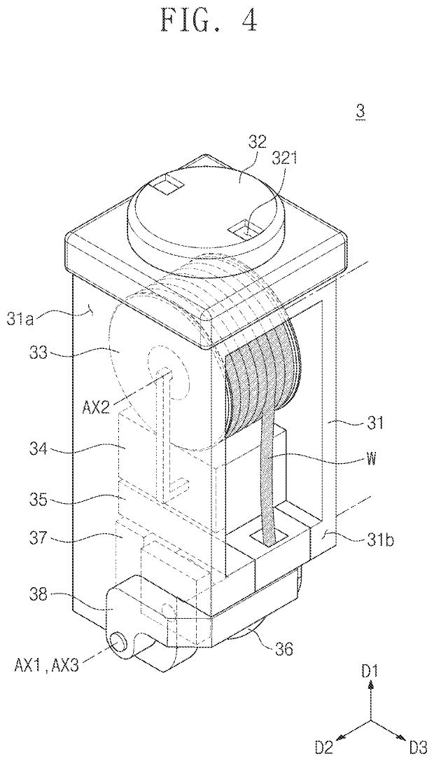

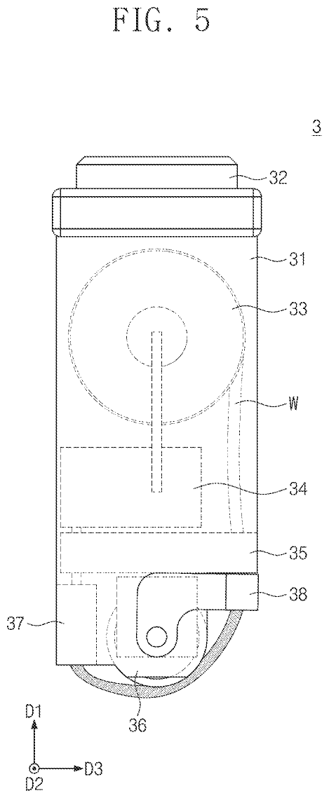

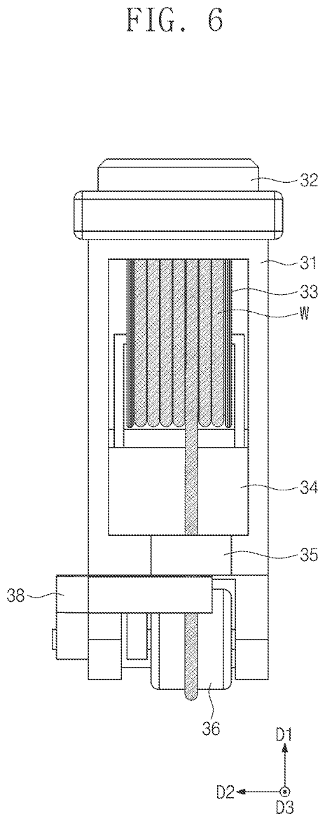

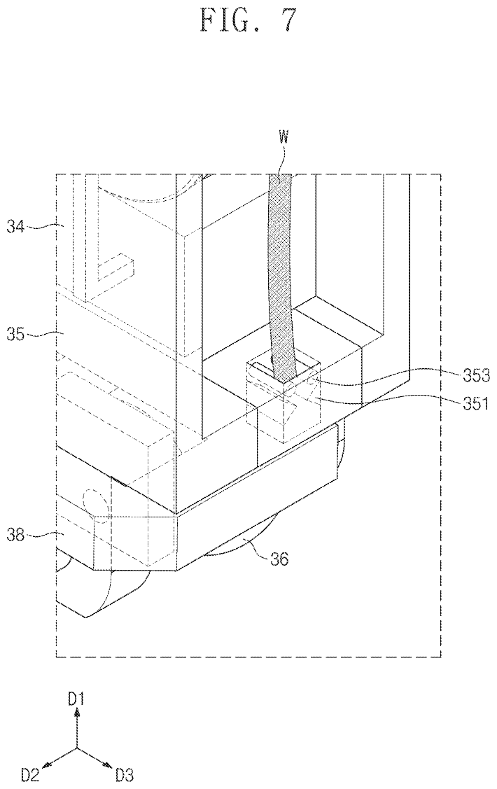

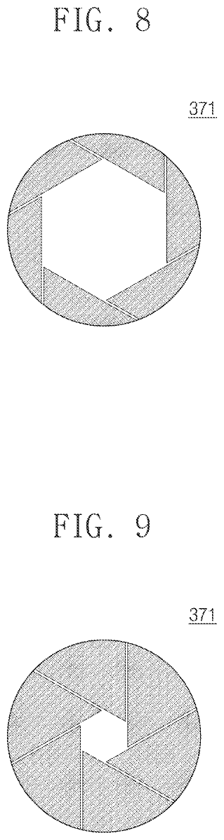

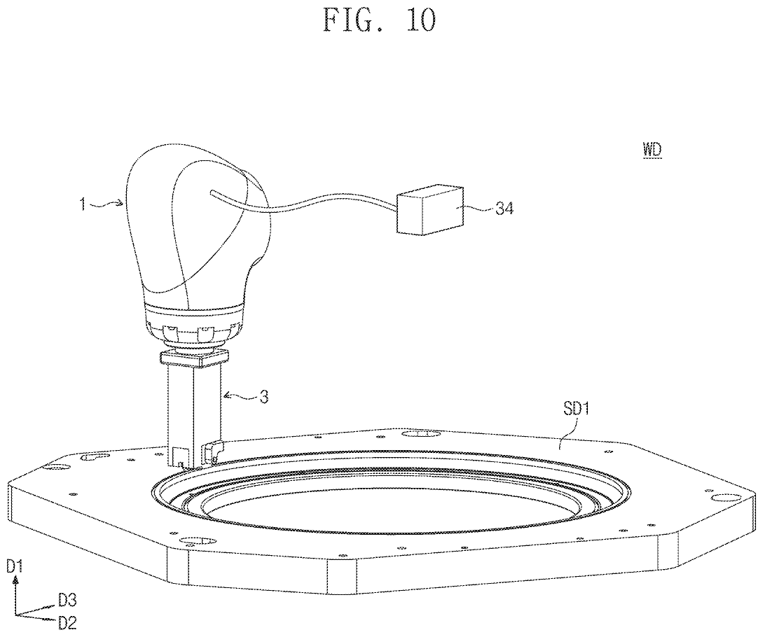

FIG. 3 illustrates an exploded perspective view showing an example of a wire gripper 3. FIG. 4 illustrates a perspective view showing an example of a wire gripper 3. FIG. 5 illustrates a front view showing an example of a wire gripper 3. FIG. 6 illustrates a side view showing an example of a wire gripper 3. FIG. 7 illustrates an enlarged perspective view of an example of a wire cutting section 35. FIG. 8 illustrates a front view showing an example of an aperture-shaped grip part 371. FIG. 9 illustrates a front view showing an example of an aperture-shaped grip part 371. FIG. 10 illustrates a perspective view showing an example of a wire processing apparatus WD.

Referring to FIGS. 3 to 6, the wire gripper 3 may include a gripper body 31, a wire supply 33, a wire cutting section 35, a pressure roller 36, a twister 37, a reloader 38, a controller 34, and a connector 32.

The gripper body 31 may support the wire supply 33. The gripper body 31 may provide an internal space (not designated by reference numeral). The gripper body 31 may have a hollow rectangular hexahedral shape. The gripper body 31 may have a partially deformed hollow rectangular hexahedral shape. The gripper body 31 may have a flat shape that allows the wire gripper 3 to press the wire W into a narrow gap. For example, referring to FIG. 4, the pressure roller 36 may rotate about a first axis AX1. The first axis AX1 may be, for example, parallel to the second direction D2. The gripper body 31 may include a first lateral surface 31a perpendicular to the first axis AX1. The gripper body 31 may include a second lateral surface 31b parallel to the first axis AX1. A width of the first lateral surface 31a may be greater than that of the second lateral surface 31b. The gripper body 31 may have an open structure. For example, the internal space of the gripper body 31 may be spatially connected to an external space. At least one of the first and second lateral surfaces 31a and 31b may have a portion having an open shape through which the internal space of the gripper body 31 is spatially connected to an external space.

The connector 32 may be combined with the gripper body 31. For example, the connector 32 may be coupled onto the gripper body 31. However, the position of the connector 32 is not limited thereto, and the connector 32 may be combined with the gripper body 31 at a position at which a press-in process of the wire W is easily performed. The connector 32 may connect the gripper body 31 and the manipulator 1 to each other. The connector 32 may be supplied with power from outside. For example, the connector 32 may be supplied with power from the manipulator 1. The connector 32 may have a cylindrical shape, but the present disclosure is not limited thereto. The connector 32 may have any other shape suitable for being combined with the manipulator 1 and supplied with power from the manipulator 1. The connector 32 may provide a fixing hole 321. The manipulator 1 may be easily connected through the fixing hole 321 to the gripper body 31. The wire gripper 3 may be supplied with power through the fixing hole 321.

The wire supply 33 may supply the wire W. The wire supply 33 may be positioned within the gripper body 31. The wire supply 33 may rotate about a second axis AX2 parallel to the first axis AX1. The wire supply 33 may have a cylindrical shape. The wire W may be wounded on an outer surface of the wire supply 33. The wire supply 33 may supply the wire W to the wire cutting section 35 and the reloader 38.

The pressure roller 36 may be positioned below the wire supply 33. The pressure roller 36 may have a cylindrical shape. The pressure roller 36 may provide a guide groove 361 that guides the wire W supplied from the wire supply 33. The wire gripper 3 may allow the guide groove 361 to press the wire W, while progressing in an intended direction. The pressure roller 36 may rotate about the first axis AX1.

The twister 37 may twist and hold the wire W. The twister 37 may be positioned on a side of the pressure roller 36. The twister 37 may be supplied through the reloader 38 with the wire W. Referring to FIGS. 8 and 9, the twister 37 may include the aperture-shaped grip part 371. However, the shape of the grip part 371 is not limited thereto, and the grip part 371 may have any other shape suitable for capable of holding the wire W while reducing a diameter of the wire W. When the grip part 371 expands, the grip part 371 may have an increased internal space. When the grip part 371 contracts, the grip part 371 may have a narrow internal space. The twister 37 may twist an end of the wire W guided by the pressure roller 36. When the wire W is positioned within the twister 37, the grip part 371 may contract such that the wire W may be rotated and held in its lengthwise direction.

The reloader 38 may drive the end of the wire W, which is supplied from the wire supply 33, to move to the twister 37. Referring to FIGS. 4 and 5, the reloader 38 may be positioned below the wire cutting section 35. The reloader 38 may drive the end of the wire W to move from the wire cutting section 35 to the twister 37. The reloader 38 may rotate about a third axis AX3 parallel to the first axis AX1. Referring to FIGS. 3 and 4, the first axis AX1 and the third axis AX3 may be the same axis. The present disclosure, however, is not limited thereto, and the third axis AX3 may be differentiated from the first axis AX1. The reloader 38 may reciprocate between the wire cutting section 35 and the twister 37, while rotating about the third axis AX3. The reloader 38 may provide a guide hole 38h through which penetrates the wire W supplied from the wire supply 33. The reloader 38 may include a wire holder capable of holding the wire W positioned in the guide hole 38h. The reloader 38 may use the wire holder to move the wire W. The wire holder may have an aperture shape. However, the shape of the wire holder is not limited thereto, and the wire holder may have any other suitable shape to hold the wire W. The wire holder may have a clamper shape. The wire holder may be shaped like a pair of rods or a plate. The reloader 38 may be supplied with the wire W from the wire supply 33. Referring to FIGS. 4 to 6, the reloader 38 may be joined with the end of the wire W released from the wire cutting section 35. The reloader 38 may drive the end of the wire W, which is supplied from the wire supply 33, to move to the twister 37.

The controller 34 may control the wire supply 33, the wire cutting section 35, the pressure roller 36, the twister 37, and the reloader 38. For example, the controller 34 may control rotation directions and rotation speeds of the wire supply 33, the wire cutting section 35, and the pressure roller 36. The controller 34 may control a grip speed and a degree of contraction and expansion of the grip part 371. The controller 34 may control a rotation direction and a rotation timing of the reloader 38. The controller 34, however, is not limited to this role. The controller 34 may control a configuration of the wire gripper 3 to press the wire W into the substrate processing apparatus SD. The controller 34 may include a single board computer (SBC). For example, the controller 34 may include Raspberry Pi, Orange Pi, Intel Galileo, Nano Pi, Asus Tinker Board, or Arduino. The controller 34 may be positioned within the gripper body 31. The present disclosure, however, is not limited thereto. Referring to FIG. 10, the wire processing apparatus WD may include the controller 34. The controller 34 may be positioned outside the gripper body 31. The controller 34 may be connected to the manipulator 1. The manipulator 1 may include a pneumatic compressor capable of applying a pneumatic pressure to the wire gripper 3. When the manipulator 1 applies a pneumatic pressure to the wire gripper 3, the controller 34 may be connected to the manipulator 1 outside the gripper body 31. The controller 34 may use a pneumatic pressure to press the wire W, while controlling the manipulator 1 and the wire gripper 3.

Referring to FIG. 7, the wire cutting section 35 may be provided. The wire cutting section 35 may include a cutter 351 and a wire roller 353. The cutter 351 may cut the wire W supplied from the wire supply 33. The wire cutting section 35 may be positioned within the gripper body 31. The wire cutting section 35 may be positioned below the wire supply 33. The wire cutting section 35 may be positioned above the reloader 38. The wire cutting section 35 may be controlled by the controller 34. For example, the controller 34 may control an operating time and an operating timing of the cutter 351. The cutter 351 may have a shape of a pair of triangular pillars, but the present disclosure is not limited thereto. The cutter 351 may have a flat plate shape. The cutter 351 may have any other shape suitable for cutting the wire W. The wire roller 353 may hold the wire W. The wire roller 353 may guide the wire W to a place between components of the cutter 351. When the wire W is cut by the cutter 351, the wire roller 353 may prevent the wire W from bouncing outwards. The wire roller 353 may be positioned on the cutter 351. The wire roller 353 may have a shape of a pair of cylinders. However, the shape of the wire roller 353 is not limited thereto. A rotation axis of the cylinder may be perpendicular to a lengthwise direction of the wire W. The wire roller 353 may have a portion in contact with the wire W, and the portion of the wire roller 353 may rotate in a downward direction to cause the wire W to move to the cutter 351 and the reloader 38.

The wire gripper 3 may further include a plurality of rotary motors that correspondingly rotate the reloader 38, the pressure roller 36, and the wire supply 33. A single rotary motor will be discussed below in the interest of convenience. The rotary motor may be controlled by the controller 34. The controller 34 may control rotation directions, rotation speeds, and rotation sequences of the plurality of rotary motors.

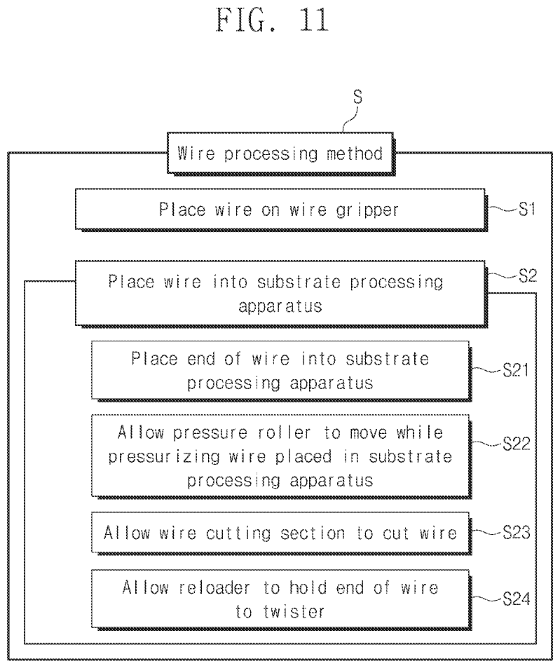

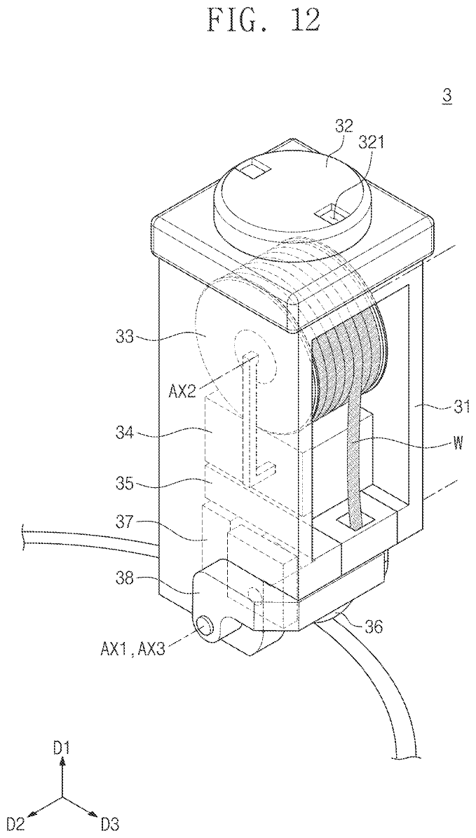

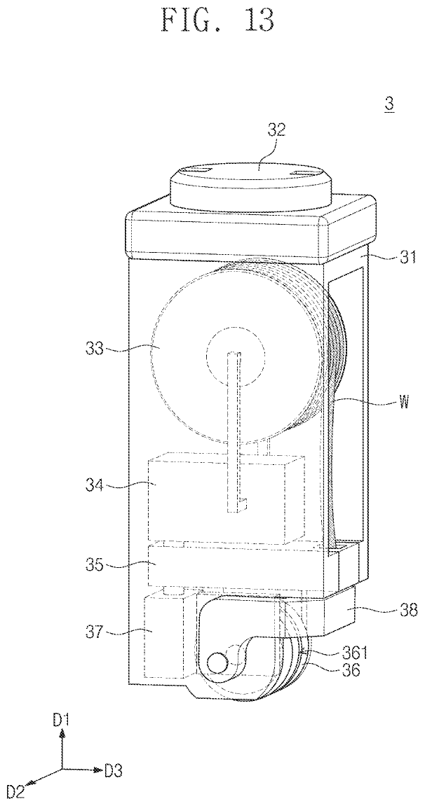

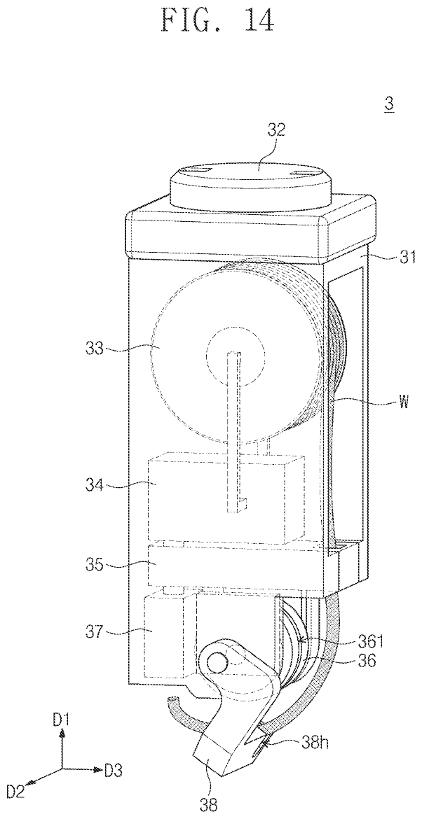

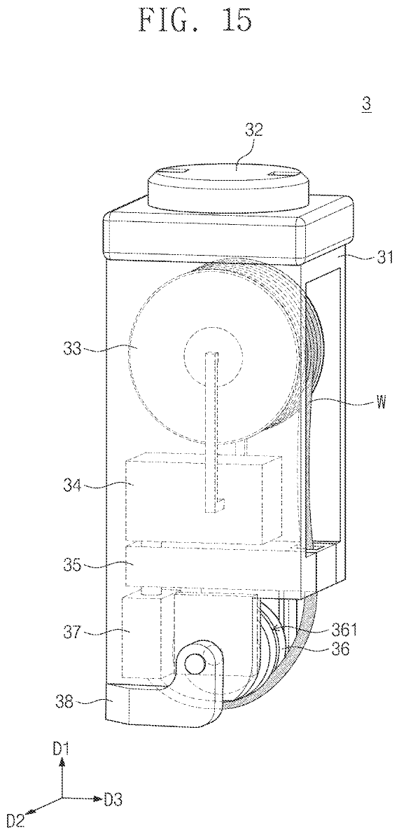

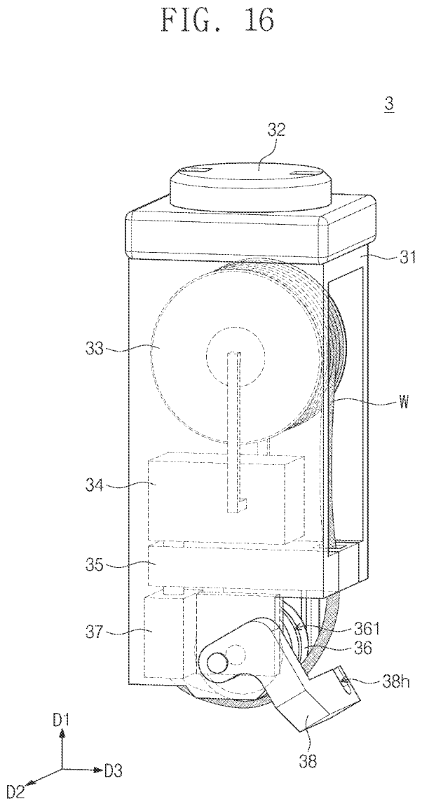

FIG. 11 illustrates a flow chart showing an example of a wire processing method S. FIG. 12 illustrates a perspective view showing an example of a wire gripper 3 according to the flow chart. FIG. 13 illustrates a perspective view showing another example of a wire gripper 3 according to the flow chart. FIG. 14 illustrates a perspective view showing another example of a wire gripper 3 according to the flow chart. FIG. 15 illustrates a perspective view showing another example of a wire gripper 3 according to the flow chart. FIG. 16 illustrates a perspective view showing another example of a wire gripper 3 according to the flow chart.

Referring to FIG. 11, the wire processing method S may include placing the wire W on the wire gripper 3 (S1) and placing the wire W into the substrate processing apparatus SD (S2). The step of placing the wire W into the substrate processing apparatus SD (S2) may include allowing the wire gripper 3 to place an end of the wire W into the substrate processing apparatus SD (S21), allowing the pressure roller 36 to move while pressurizing the wire W placed in the substrate processing apparatus SD (S22), allowing the wire cutting section 35 to cut the wire W (S23), and allowing the reloader 38 to hold the end of the wire W to the twister 37 (S24).

Referring to FIG. 12, the wire gripper 3 may be provided which performs a press-in process of the wire W. When the wire gripper 3 begins the press-in process of the wire W, an end of the wire W may be held to the twister 37. The wire W may be fixed with its diameter reduced by the twister 37. The twister 37 may allow the wire W to be easily pressed into the groove SD11 of the substrate processing apparatus SD. When the pressure roller 36 moves while rotating along the groove SD11 of the substrate processing apparatus SD, the end of the wire W may be released from the twister 37. The wire supply 33 may rotate to supply the pressure roller 36 with the wire W. The pressure roller 36 may allow the guide groove 361 to press the wire W into the groove SD11 of the substrate processing apparatus SD. The wire gripper 3 may move while being provided with power from the manipulator 1.

Referring to FIG. 13, the wire gripper 3 may be provided which terminates the press-in process of the wire W. Before the termination of the press-in process of the wire W, the cutter 351 may cut the wire W in the wire cutting section 35. The pressure roller 36 may rotate to press the wire W that remains between the wire cutting section 35 and the pressure roller 36, and thus the press-in process of the wire W may be terminated.

Referring to FIGS. 14 to 16, the wire gripper 3 may be provided which is in the middle of preparation of a next press-in process of the wire W. The reloader 38 may be supplied with a wire W from the wire supply 33. The wire W may pass through the cutter 351 to be supplied to the reloader 38. The wire holder may cause the reloader 38 to contact a portion or an end of the wire W. The reloader 38 may hold the portion or the end of the wire W. The reloader 38 may rotate about the third axis AX3 to supply the twister 37 with the end of the wire W. The reloader 38 may place the wire W on the guide groove 361, while rotating about the third axis AX3. As the wire W is positioned on the guide groove 361, the wire W may be pressed in even though the wire gripper 3 moves. When the reloader 38 supplies the end of the wire W, the twister 37 may expand the grip part 371 to place the wire W into the twister 37. The twister 37 may contract the grip part 371 to hold the wire W in the twister 37. The extraction of the grip part 371 may reduce a diameter of the wire W. When an end of the wire W is held to the twister 37, the reloader 38 may rotate about the third axis AX3 to return to its initial position.

According to a wire gripper, a wire processing apparatus including the same, and a wire processing method using the same in accordance with some implementations of the present disclosure, a wire may be automatically pressed into a substrate processing apparatus. For example, a manipulator may press the wire into a groove of the substrate processing apparatus, while moving the wire gripper. A controller may control a wire supply, a wire cutting section, a reloader, a pressure roller, and a twister, thereby performing an automatic wire press-in process.

According to a wire gripper, a wire processing apparatus including the same, and a wire processing method using the same in accordance with some implementations of the present disclosure, as a wire has a reduced diameter, the wire may be pressed into even a narrow groove. A grip part of a twister may include a structure capable of reducing the diameter of the wire and holding the wire. For example, the grip part may have an aperture shape. As the wire is fixed with its reduced diameter, the wire may be pressed into a groove whose width is less than a diameter of the wire to which no external force is applied. After the wire is pressed into the groove, when the external force is eliminated, the wire may have an increased diameter to effectively fill the groove.

According to a wire gripper, a wire processing apparatus including the same, and a wire processing method using the same of the present disclosure, a wire may be automatically pressed into a substrate processing apparatus.

According to a wire gripper, a wire processing apparatus including the same, and a wire processing method using the same of the present disclosure, a next wire press-in process may be automatically prepared after a previous wire press-in process.

According to a wire gripper, a wire processing apparatus including the same, and a wire processing method using the same of the present disclosure, an end of a wire may be twisted and held in its lengthwise direction, and thus the wire may be pressed with a reduced diameter thereof.

According to a wire gripper, a wire processing apparatus including the same, and a wire processing method using the same of the present disclosure, a wire may be supplied from a wire supply and then an end of the wire may be held to a twister.

Effects of the present disclosure is not limited to the mentioned above, other effects which have not been mentioned above will be clearly understood to those skilled in the art from the following description.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

Although the present disclosure has been described in connection with some implementations of the present disclosure illustrated in the accompanying drawings, it will be understood to those skilled in the art that various changes and modifications may be made without departing from the technical spirit and essential feature of the present disclosure. It therefore will be understood that the implementations described above are just illustrative but not limitative in all aspects.

What is claimed is:

1. A wire gripper, comprising:
a gripper body;
a wire supply in the gripper body, the wire supply configured to supply a wire;
a wire cutting section including a cutter configured to cut the wire supplied from the wire supply;
a pressure roller below the wire supply, the pressure roller defining a guide groove configured to guide the wire supplied from the wire supply, the pressure roller configured to rotate around a first axis;
a twister on a side of the pressure roller; and
a reloader configured to drive an end of the wire to move from the wire supply to the twister,
wherein the twister is configured to hold and twist the end of the wire guided by the pressure roller.

2. The wire gripper of claim 1, wherein the twister is configured to twist the end of the wire in a lengthwise direction of the wire.

3. The wire gripper of claim 2, comprising a controller in the gripper body, wherein the controller is configured to control the wire supply, the wire cutting section, the pressure roller, the twister, and the reloader.

4. The wire gripper of claim 3, wherein the controller includes a single board computer (SBC).

5. The wire gripper of claim 1, comprising a connector combined with the gripper body, wherein the connector is supplied with power from outside of the wire gripper.

6. The wire gripper of claim 1, wherein
the wire supply has a cylindrical shape that is configured to rotate a second axis parallel to the first axis,
the reloader is configured to rotate a third axis parallel to the first axis, and
the reloader includes a wire holder combined with the end of the wire supplied from the wire supply.

7. The wire gripper of claim 3, comprising a plurality of rotary motors that are controlled by the controller to rotate the wire supply and the pressure roller, respectively.

8. The wire gripper of claim 1, wherein the gripper body includes:
a first lateral surface perpendicular to the first axis; and
a second lateral surface parallel to the first axis,
wherein a width of the first lateral surface is greater than a width of the second lateral surface.

9. The wire gripper of claim 2, wherein the twister includes an aperture-shaped grip part and is configured to hold and rotate the wire in a lengthwise direction.

10. A wire gripper, comprising:
a gripper body;
a rotatable cylindrical wire supply in the gripper body;
a wire cutting section configured to cut a wire supplied from the rotatable cylindrical wire supply;
a cylindrical pressure roller configured to guide a movement of the wire;
a twister including an aperture-shaped grip part configured to twist an end of the wire guided by the pressure roller; and
a connector supplied with power from outside of the wire gripper.

11. The wire gripper of claim 10, comprising a rotatable reloader configured to allow the twister to hold the end of the wire supplied from the wire supply.

12. The wire gripper of claim 10, wherein the connector provides a fixing hole that can connect the gripper body to an external device.

13. The wire gripper of claim 10, comprising a controller in the gripper body, wherein the controller is configured to control the wire supply, the wire cutting section, and the reloader, and
wherein the connector is configured to receive a power from outside and to transmit the power to the controller.

14. The wire gripper of claim 10, wherein the wire cutting section includes a cylindrical wire roller configured to hold the wire that is cut.

15. The wire gripper of claim 11, wherein
the reloader provides a guide hole through which the wire supplied from the wire supply passes, and
the reloader includes an aperture-shaped wire holder that is configured to hold the wire placed in the guide hole.

16. The wire gripper of claim 11, wherein the wire gripper includes a plurality of rotary motors that are configured to rotate the reloader, the pressure roller, and the wire supply, respectively.

17. A wire gripper, comprising:
a wire supply configured to supply the wire;
a wire cutting section including a cutter that is configured to cut the wire supplied from the wire supply;
a twister configured to hold the end of the wire;
a reloader configured to drive the end of the wire to move from the wire cutting section to the twister, and
a pressure roller configured to pressurize the wire toward the substrate processing apparatus, the wire being supplied from the wire supply,
wherein the twister includes an aperture-shaped grip part and is configured to hold and rotate the wire in a lengthwise direction.

18. The wire gripper of claim 17, comprising a controller in the gripper body, wherein the controller is configured to control the wire supply, the wire cutting section, the pressure roller, the twister, and the reloader.

19. The wire gripper of claim 18, wherein the controller includes a single board computer (SBC).

20. The wire gripper of claim 19, comprising a connector combined with the gripper body, wherein the connector is supplied with power from outside of the wire gripper.
